(19) United States
(12) Patent Application Publication
(10) Pub. No.: US 2025/0351518 A1
(43) Pub. Date: Nov. 13, 2025

(54) DOUBLE-SIDED CONTACT IN BACKSIDE POWER DISTRIBUTION NETWORK INTEGRATION SCHEME

(71) Applicant: QUALCOMM Incorporated, San Diego, CA (US)

(72) Inventors: John Jianhong ZHU, San Diego, CA (US); Junjing BAO, San Diego, CA (US); Abhishek JAIN, San Diego, CA (US); Giridhar NALLAPATI, San Diego, CA (US)

(21) Appl. No.: 18/659,975

(22) Filed: May 9, 2024

(51) Int. Cl. H01L 29/417; H01L 23/528

(52) U.S. Cl. CPC H10D 64/254; H01L 23/5286

(57) ABSTRACT

Disclosed are semiconductor devices with double sided contacts—frontside and backside contacts to source/drain epitaxials. As a result, resistance can be significantly reduced. Also, deep bar vias need not reach the backside contact, which helps with process margins.

### BACKGROUND OF THE DISCLOSURE

### 1. Field of the Disclosure

This disclosure relates generally to die packages or modules, and more specifically, but not exclusively, to semiconductor devices/modules that include double-sided contact in backside power distribution network (BSPDN) and fabrication techniques thereof.

### 2. Description of the Related Art

Integrated circuit (IC) technology has achieved great strides in advancing computing power through miniaturization of active components. In current 5G and WiFi6 radio frequency (RF) frontend packages/modules, RFIC chips such as switches (SW), low noise amplifiers (LNA), power amplifiers (PA), digital amplifiers (DA), filters, etc. are placed side-by-side in a package, e.g., for an RF frontend module.

One issue is delivering power to devices and circuits, especially as the dimensions of the devices continue to shrink. BSPDN is likely to become the future trend for continuous scaling. Unfortunately, it is very challenging to achieve low resistance in backside contact due to low thermal budget that limits the quality of silicidation. Accordingly, there is a need for systems, apparatus, and methods that overcome the deficiencies of conventional semiconductor devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor device is disclosed. The semiconductor device may comprise a source/drain (S/D) epitaxial. The semiconductor device may also comprise a frontside contact above and electrically coupled with the S/D epitaxial through an upper surface of the S/D epitaxial. The semiconductor device may further comprise a backside contact below and electrically coupled with the S/D epitaxial through a lower surface of the S/D epitaxial. The semiconductor device may yet comprise a deep bar via on sides of the frontside contact and of the backside contact. The deep bar via may be electrically coupled with the frontside contact through a first side surface of the frontside contact and electrically coupled with the backside contact through a first side surface of the backside contact. The semiconductor device may yet further comprise a backside power rail below and electrically coupled with the backside contact through a lower surface of the backside contact.

A method of fabricating an exemplary semiconductor device is disclosed. The method may comprise forming comprise a source/drain (S/D) epitaxial. The method may also comprise forming a frontside contact above and electrically coupled with the S/D epitaxial through an upper surface of the S/D epitaxial. The method may further comprise forming a backside contact below and electrically coupled with the S/D epitaxial through a lower surface of the S/D epitaxial. The method may yet comprise forming a deep bar via on sides of the frontside contact and of the backside contact. The deep bar via may be electrically coupled with the frontside contact through a first side surface of the frontside contact and electrically coupled with the backside contact through a first side surface of the backside contact. The method may yet further comprise forming a backside power rail below and electrically coupled with the backside contact through a lower surface of the backside contact.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A and 1B illustrate top and cross section views of a conventional semiconductor device with frontside contact and deep bar via.

FIGS. 2A and 2B illustrate top and cross section views of a conventional semiconductor device with direct backside contact.

FIG. 3A illustrates a top view of a semiconductor device in accordance with one or more aspects of the disclosure.

FIGS. 3B and 3C illustrate cross section views in orthogonal directions of the semiconductor device of FIG. 3A in accordance with one or more aspects of the disclosure.

FIGS. 4A-4H illustrate examples of stages of fabricating a semiconductor device in accordance with one or more aspects of the disclosure.

FIGS. 5-7 illustrate flow charts of example methods of manufacturing a semiconductor device in accordance with at one or more aspects of the disclosure.

FIG. 8 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor devices and methods for fabricating the same. In an aspect, the semiconductor device may comprise a source/drain (S/D) epitaxial, a frontside contact, a backside contact, a deep bar via, and a backside power rail below. The frontside contact may be above and electrically coupled with the S/D epitaxial through an upper surface of the S/D epitaxial. The backside contact may be below and electrically coupled with the S/D epitaxial through a lower surface of the S/D epitaxial. The deep bar via may be formed on sides of the frontside contact and of the backside contact. The deep bar via may be electrically coupled with the frontside contact through a first side surface of the frontside contact and electrically coupled with the backside contact through a first side surface of the backside contact. The backside power rail may be below and electrically coupled with the backside contact through a lower surface of the backside contact.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

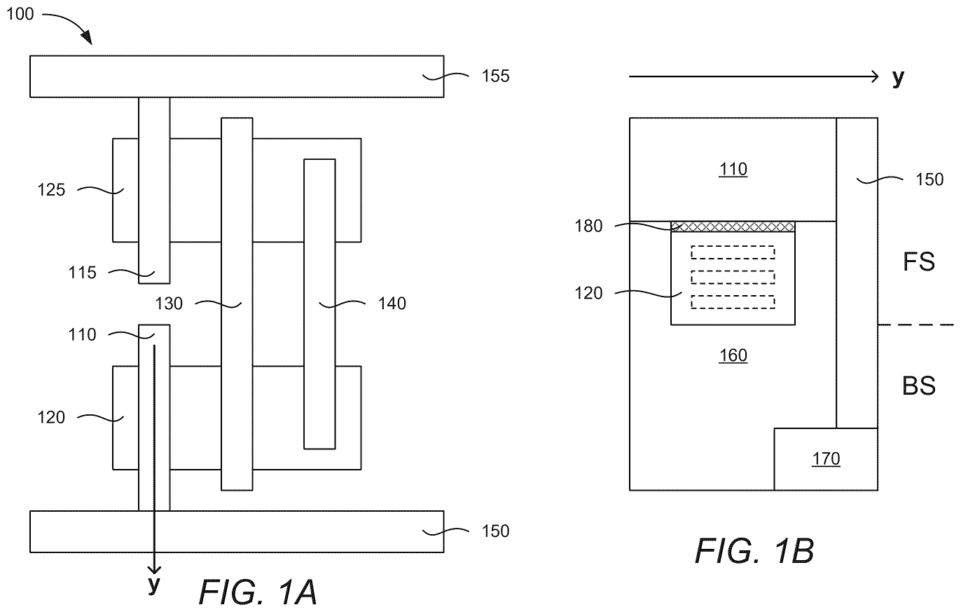

As indicated above, it can challenging to achieve low resistance in power distribution networks of semiconductor devices. FIG. 1A illustrates a top view of a conventional semiconductor device with frontside contact in BSPDN and deep bar via. As seen, the conventional semiconductor device 100 includes source/drain (S/D) epitaxials 120, 125. To differentiate, these may be referred to as first S/D epitaxial 120 and second S/D epitaxial 125. The first S/D epitaxial 120 is of one type (e.g., n-type) and the second S/D epitaxial 125 is of an opposite type (e.g., p-type).

First and second frontside contacts 110, 115 are above upper surfaces of the first and second S/D epitaxials 120, 125, respectively. The first frontside contact 110 is electrically coupled with the first S/D epitaxial 120, and the second frontside contact 115 is electrically coupled with the second S/D epitaxial 125. A connection contact 140 is above and in contact with the first and second S/D epitaxials 120, 125. That is, the connection contact 140 is electrically coupled to both the first and second S/D epitaxials 120, 125.

A gate 130 is above both the first and second S/D epitaxials 120, 125. The gate 130 is not electrically coupled with either the first S/D epitaxial 120 or the second S/D epitaxial 125. However, when a voltage is applied to the gate 130, a first conductive channel can be formed in the first S/D epitaxial 120 between the first frontside contact 110 and the connection contact 140. Also when the voltage is applied to the gate 130, a second conductive channel can be formed in the second S/D epitaxial 125 between the second frontside contact 115 and the connection contact 140. Thus, a circuit formed by the first and second frontside contacts 110, 115, first and second S/D epitaxials 120, 125, the gate 130 and the connection contact 140 is an inverter.

First and second deep bar vias 150, 155 provides power to the semiconductor device 100, i.e., to the circuit. The first deep bar via 150 provides Vss voltage (assuming that the first S/D epitaxial 120 is n-type), and the second deep bar via 155 provides Vdd voltage (assuming that the second S/D epitaxial 125 is p-type).

FIG. 1B illustrates a cross section view of the semiconductor device 100 of FIG. 1A along the cross section ‘y’. In describing FIG. 1B, the term “first” will be dropped from the components of the semiconductor device 100 for generality sake. As seen, semiconductor device 100 along this ‘y’ cross section includes the S/D epitaxial 120, and the frontside contact 110 above the S/D epitaxial 120. Regarding the S/D epitaxial 120, note that there are three smaller dashed rectangles within a larger rectangle. The three smaller dashed rectangles represent ghosts of nanosheets upon which conductive channels can be formed. The S/D epitaxial 120 and the frontside contact 110 are both electrically conductive. As seen, the lower surface of the S/D epitaxial 120 is viewed as being a boundary between frontside (FS) above and backside (BS) below.

A silicide 180 is in between the frontside contact 110 and the S/D epitaxial 120. The silicide 180 is electrically conductive and is in contact with a lower surface of the frontside contact 110 and with the upper surface of the S/D epitaxial 120. A dielectric 160 is formed below the frontside contact 110, the silicide 180 and the S/D epitaxial 120. The dielectric 160 encapsulates the silicide 180 and the S/D epitaxial 120.

A deep bar via 150 is formed to be in contact with a first (e.g., right) side surface of the and a first (e.g., right) side surface of the dielectric 160. The deep bar via 150, which is conductive, spans the front and backsides of the semiconductor device 100. Note that the height of deep bar via 150 is quite substantial. For example, the upper surface of the deep bar via 150 is even or coplanar with the upper surface of the frontside contact.

A backside power rail 170 is formed below and is in contact with a lower surface of the deep bar via 150. Note that the conductive path from the backside power rail 170 to the S/D epitaxial 120 is fairly long. That is, voltage (e.g., Vss) applied to the backside power rail 170 is provided to the S/D epitaxial 120 through the deep bar via 150, the frontside contact 110, and the silicide 180. Due to the long path, there can be significant resistance loss in power delivered to the S/D epitaxial 120.

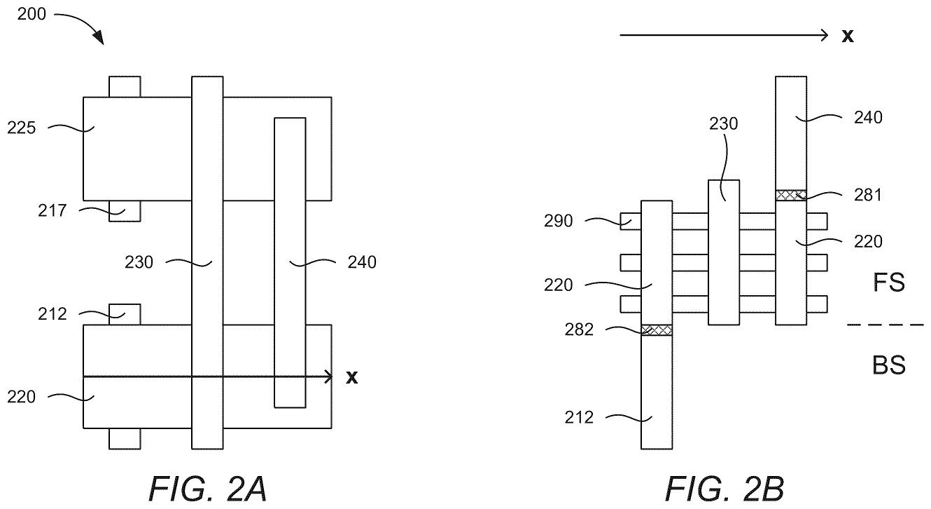

FIG. 2A illustrate top view of a conventional semiconductor device with direct backside contact in BSPDN. As seen, the conventional semiconductor device 200 includes first and second source/drain (S/D) epitaxials 220, 225. The first S/D epitaxial 220 is of one type (e.g., n-type) and the second S/D epitaxial 225 is of an opposite type (e.g., p-type).

First and second backside contacts 212, 217 are below the lower surfaces of the first and second S/D epitaxials 220, 225, respectively. The first backside contact 212 is electrically coupled with the first S/D epitaxial 220, and the second backside contact 217 is electrically coupled with the second S/D epitaxial 225. A connection contact 140 is above and in contact with the first and second S/D epitaxials 220, 225. That is, the connection contact 240 is electrically coupled to both the first and second S/D epitaxials 120, 125.

A gate 230 is above both the first and second S/D epitaxials 220, 225. The gate 230 is not electrically coupled with either the first S/D epitaxial 220 or the second S/D epitaxial 225. However, when a voltage is applied to the gate 230, a first conductive channel can be formed in the first S/D epitaxial 220 between the first backside contact 212 and the connection contact 240. Also when the voltage is applied to the gate 230, a second conductive channel can be formed in the second S/D epitaxial 225 between the second backside contact 215 and the connection contact 240. Thus, similar to the semiconductor device 100, an inverter circuit can be formed, this time by the first and second backside contacts 212, 217, first and second S/D epitaxials 220, 225, the gate 230 and the connection contact 240. While not shown, power voltages—e.g., Vss, Vdd—may be delivered from the backside to the first and second backside contacts 212, 217.

FIG. 2B illustrates a cross section view of the semiconductor device 200 of FIG. 2A along the cross section ‘x’. Again, in describing FIG. 2B, the term “first” will be dropped from the components of the semiconductor device 200 for generality sake. As mentioned above, when the voltage is applied to the gate 230, a conductive channel can be formed in the S/D epitaxial 220 between the backside contact 212 and the connection contact 240. The conductive channels may be formed through nanosheets 290 that span the length of the S/D epitaxial 220. As seen, the lower surface of the S/D epitaxial 220 is viewed as being a boundary between frontside (FS) above and backside (BS) below.

A backside silicide 282 is in between the backside contact 212 and the S/D epitaxial 220. The backside silicide 282 is electrically conductive and is in contact with the upper surface of the backside contact 212 and with the lower surface of the S/D epitaxial 220. A connection silicide 281 is in between the connection contact 240 and the S/D epitaxial 220. The connection silicide 281 is electrically conductive and is in contact with the lower surface of the connection contact 240 and with the upper surface of the S/D epitaxial 220.

Again, while not shown, it may be assumed that a backside power rail is in direct contact with the backside contact 212. As such, power to the S/D epitaxial can be provided through a relatively short path—through the backside contact 212 and the backside silicide 282.

Unfortunately, the resistance of the path can be high resulting in significant resistance loss. In a conductive path such as this, bulk of the resistance is due to the resistance of the silicide interface. That is, the backside silicide 282 can constitute a significant portion, even majority, of the path resistance. Thus, the quality of the backside silicide 282 is important.

When fabricating semiconductor devices with front and backsides such as the semiconductor device 200, the process normally entails forming the frontside more or less completely, and then forming the backside. When forming the frontside, high temperature processing (e.g., above 400° C.) may be used when forming silicides such as the connection silicide 281. As a result, high quality (e.g., low resistance) silicides may be formed.

However, when forming the backside, the thermal budget is limited, i.e., low temperature processing (e.g., below 400° C.) is used. This is so that the already completed frontside is not subjected to high temperatures so that the integrity of the frontside is maintained. One downside of low temperature processing is that the quality of the silicides formed can be low resulting in high resistance of the silicide and thus high resistance of the conductive path.

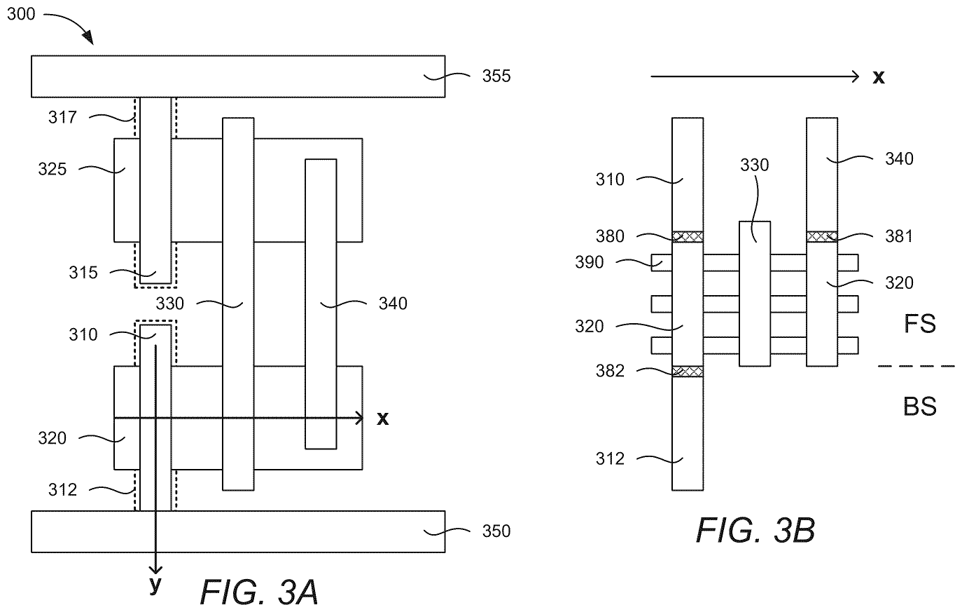

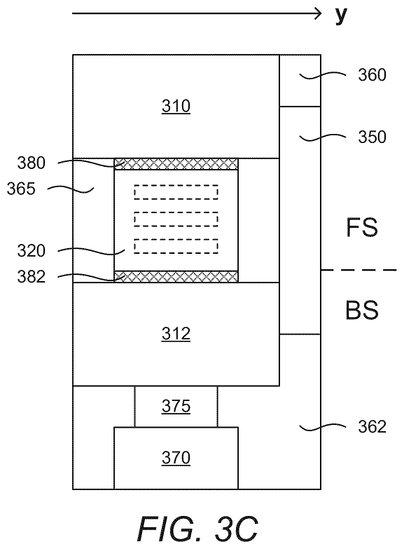

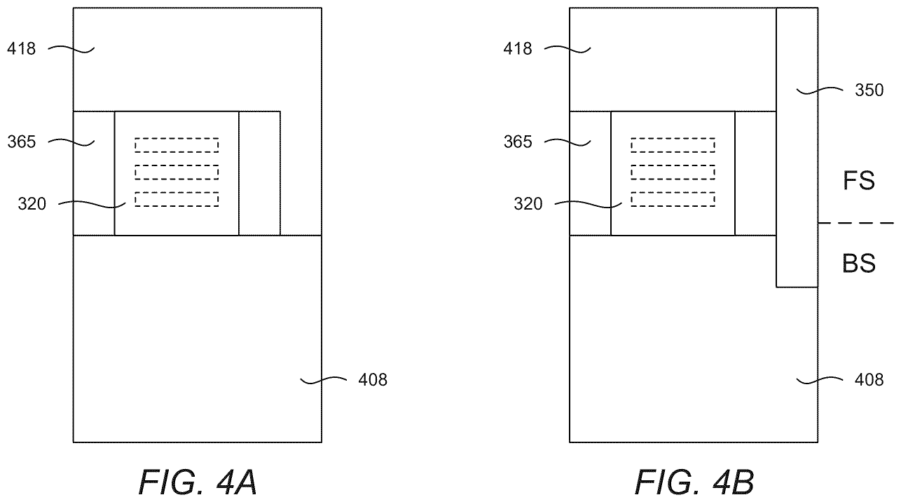

To address these and other issues of the conventional semiconductor device, it is proposed to provide double sided contacts in BSPDN so as to reduce conductive path resistance as well as to reduce parasitic capacitance. This is illustrated in FIGS. 3A-3C. FIG. 3A illustrates a top view of a semiconductor device 300 in accordance with one or more aspects of the disclosure. As seen, the semiconductor device 300 may include source/drain (S/D) epitaxials 320, 325. To differentiate between them, these may be referred to as first S/D epitaxial 320 and second S/D epitaxial 325. The first S/D epitaxial 320 may be of one type (e.g., n-type) and the second S/D epitaxial 325 may be of an opposite type (e.g., p-type).

First and second frontside contacts 310, 315 may be formed above upper surfaces of the first and second S/D epitaxials 320, 325, respectively. The first frontside contact 310 may be electrically coupled with the first S/D epitaxial 320, and the second frontside contact 315 may be electrically coupled with the second S/D epitaxial 125. A connection contact 340 may be formed above and in contact with the first and second S/D epitaxials 320, 325. More generally, the connection contact 340 may be electrically coupled to both the first and second S/D epitaxials 320, 325.

First and second backside contacts 312, 317 (illustrated as dashed boxes) may be formed below the lower surfaces of the first and second S/D epitaxials 220, 225, respectively. The first backside contact 312 may be electrically coupled with the first S/D epitaxial 320, and the second backside contact 317 may be electrically coupled with the second S/D epitaxial 325. In an aspect, the connection contact 340 and/or the backside contact 312 may be formed from metals such as tungsten (W), cobalt (Co), molybdenum (Mo), etc.

A gate 330 may be formed above both the first and second S/D epitaxials 320, 325. The gate 230 is not electrically coupled with either the first S/D epitaxial 320 nor the second S/D epitaxial 325. However, when a voltage (e.g., Vg) is applied to the gate 330, a first conductive channel can be formed in the first S/D epitaxial 320 between the first frontside/backside contacts 310, 312 and the connection contact 340. Also when the voltage is applied to the gate 330, a second conductive channel can be formed in the second S/D epitaxial 325 between the second frontside/backside contact 315, 317 and the connection contact 340. Thus, an inverter circuit can be formed by the first and second frontside contacts 310, 315, first and second backside contacts 312, 317, first and second S/D epitaxials 320, 325, the gate 330 and the connection contact 340. It is noted that the inverter circuit is merely an example. That is, circuits other than inverter may be formed.

First and second deep bar vias 350, 355 may be configured to provide power to the semiconductor device 300, i.e., to the circuit. For example, the first deep bar via 350 may be configured to provide Vss voltage (assuming that the first S/D epitaxial 220 is n-type), and the second deep bar via 355 may be configured to provide Vdd voltage (assuming that the second S/D epitaxial 325 is p-type).

FIG. 3B illustrates a cross section view of the semiconductor device 300 of FIG. 3A along the cross section ‘x’, and FIG. 3C illustrates a cross section view of the semiconductor device 300 of FIG. 3A along the cross section ‘y’. In describing FIGS. 3B and 3C, terms such as “first” and “second” will be dropped from the components of the semiconductor device 300 for generality sake. For example, the description of cross sections ‘x’ and ‘y’ can be readily applied to horizontal and vertical cross sections of the S/D epitaxial 325.

As indicated above, when the voltage is applied to the gate 330, a conductive channel can be formed in the S/D epitaxial 320 between the backside contact 312 and the connection contact 340. The conductive channels may be formed through nanosheets 390 that span the length of the S/D epitaxial 320 as seen in FIG. 3B. In FIG. 3C, ghosts of the nanosheets are represented in the three smaller dashed rectangles within a larger rectangle. In FIG. 3C, the cross-sectional shape of the S/D epitaxial 320 is a rectangle. However, this is merely an example, and the shape is not so limited. For example, another shape of the S/D epitaxial 320 may be hexagonal. As seen in both FIGS. 3B and 3C, the lower surface of the S/D epitaxial 220 is viewed as being a boundary between frontside (FS) above and backside (BS) below.

As seen in FIGS. 3B and 3C, a frontside interface 380 may be formed in between the frontside contact 310 and the S/D epitaxial 320. In an aspect, the frontside interface 380 may comprise a silicide such as titanium silicide (TiSi). The frontside interface 380 may be electrically conductive, and may be electrically coupled with the frontside contact 310 and with the S/D epitaxial 320. For example, the frontside interface 380 may be in contact with the lower surface of the frontside contact 310 and/or with the upper surface of the S/D epitaxial 320.

As a result, the frontside contact 310 may be formed above and electrically coupled with the S/D epitaxial 320 through an upper surface of the S/D epitaxial 320, e.g., with the frontside interface 380. In an aspect, the frontside contact 310 may be formed from conductive metals such as tungsten (W), cobalt (Co), molybdenum (Mo), etc.

Also, a backside interface 382 may be formed in between the backside contact 312 and the S/D epitaxial 320. In an aspect, the backside interface 382 may comprise a silicide such as TiSi. The backside interface 382 may be electrically conductive, and may be electrically coupled with the backside contact 312 and with the S/D epitaxial 320. For example, the backside interface 382 may be in contact with the upper surface of the backside contact 312 and/or with the lower surface of the S/D epitaxial 320. In an aspect, the backside contact 312 may be formed from conductive metals such as W, Co, Mo, etc.

As a result, the backside contact 312 may be formed below and electrically coupled with the S/D epitaxial 320 through a lower surface of the S/D epitaxial 320, e.g., with the backside interface 382. In an aspect, the backside contact 312 may be formed from conductive metals such as W, Co, Mo, etc.

A connection interface 381 (see FIG. 3B) may be formed in between the connection contact 340 and the S/D epitaxial 320. The connection interface 381 may be electrically conductive, and may be electrically coupled with the connection contact 340 and with the S/D epitaxial 320. For example, the connection interface 381 may be in contact with the lower surface of the connection contact 340 and/or with the upper surface of the S/D epitaxial 320. In an aspect, the connection contact 340 may be formed from conductive metals such as W, Co, Mo, etc.

A deep bar via 350 may be formed on sides of the frontside contact 310 and of the backside contact 312 (see FIG. 3C). The deep bar via 350 may be electrically coupled with the frontside contact 310 through a first side surface (e.g., right side surface) of the frontside contact 310. The deep bar via 350 may also be electrically coupled with the backside contact 312 through a first side surface (e.g., right side surface) of the backside contact 312. In an aspect, the deep bar via 350 may be formed from conductive metals such as copper (Cu), aluminum (Al), etc.

A backside power rail 370 may be formed below and electrically coupled with the backside contact 312 through a lower surface of the backside contact 312. The backside power rail 370 may be a part of back metal, e.g., BMO, of the semiconductor device 300. The backside power rail 370 may be configured to deliver power voltage (e.g., Vss, Vdd, etc.) to the S/D epitaxial 320. In an aspect, the backside power rail 370 may be formed from conductive metals such as Cu, Al, etc.

The electrical coupling between the backside contact 312 and the backside power rail 370 may be provided through a backside power connect 375 formed in between the backside contact 312 and the backside power rail 370. For example, the backside power connect 375 may be electrically conductive and in contact with the lower surface of the backside contact 312 and with an upper surface of the backside power rail 370. In an aspect, the backside power connect 375 may be formed from conductive metals such as W, Co, Mo, etc.

As seen, there can be two conductive paths from the backside power rail 370 to the S/D epitaxial 320. The first path includes the backside power connect 375, the backside contact 312, and the backside interface 382. The second path includes the backside power connect 375, the backside contact 312, the deep bar via 350, the frontside contact 310, and the frontside interface 380. Compared to the conventional semiconductor devices 100 and 200, the proposed semiconductor device 300 frontside & backside S/D epitaxial double-sided contact can offer much lower contact resistance (as much as 40% lower) due to silicidation on both sides.

Note that in FIG. 3C, the deep bar via 350 can be recessed, to make the deep bar via 350 shorter (e.g., compare with the deep bar via 150 of FIG. 1B). Shorter deep bar vias 350 can help to reduce parasitic capacitance. In an aspect, an upper surface of the deep bar via 350 may be lower than an upper surface of the frontside contact 310. This upper recessed area may be filled with a frontside dielectric 360. That is, the frontside dielectric 360 may be formed on the upper surface of the deep bar via 350 and on the first side surface of the frontside contact 310. The upper surface of the frontside dielectric 360 may be coplanar or substantially coplanar with the upper surface of the frontside contact 310.

Alternatively or in addition thereto, a lower surface of the deep bar via 350 may be higher than a lower surface of the backside contact 312. This lower recessed area may be filled with a backside dielectric 362. That is, the backside dielectric 362 may be formed on the lower surface of the deep bar via 350 and on the first side surface of the backside contact 312. In an aspect, the backside dielectric 362 may also encapsulate the side surfaces of the backside power connect 375 and the backside power rail 370.

In FIG. 3C, an epi-dielectric 365 may be formed on first and second side surfaces of the S/D epitaxial 320. For ease of reference, the S/D epitaxial 320 and the epi-dielectric 365 together may be referred to as “epi-structure”.

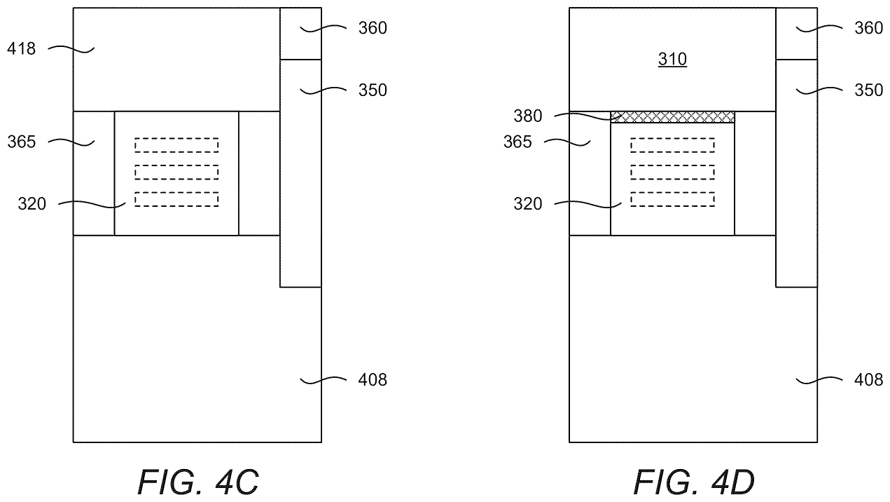

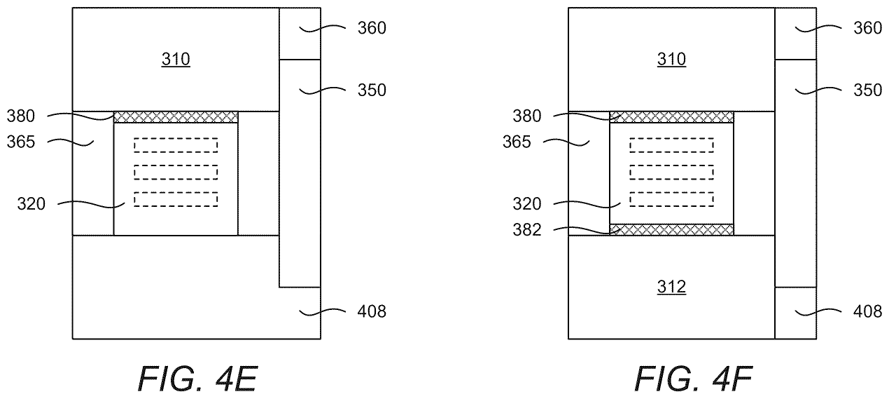

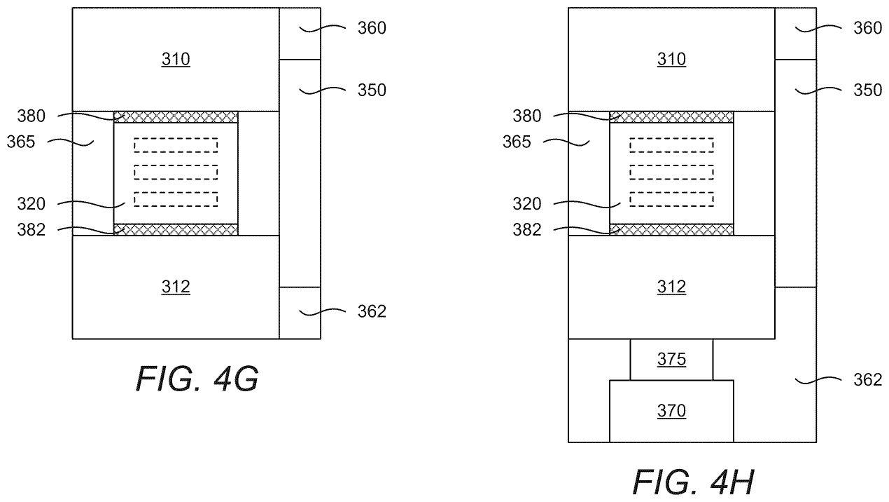

FIGS. 4A-4H illustrate examples of stages of fabricating a semiconductor device-such as the semiconductor device 300—in accordance with at one or more aspects of the disclosure.

FIG. 4A illustrates a stage in which a temporary insulator 418 may be formed on upper and first side surfaces of an epi-structure 320, 365. The epi-structure 320, 365 may be provided on a temporary substrate 408.

FIG. 4B illustrates a stage in which the deep bar via 350 may be formed on the first side surface of the epi-structure 320, 365 and within a portion the temporary substrate 408. Lower surface of the deep bar via 350 may be lower than lower surface of the epi-structure 320, 365.

FIG. 4C illustrates a stage in which upper portion of the deep bar via 350 may be recessed and the recessed portion may be filled with the frontside dielectric 360.

FIG. 4D illustrates a stage in which the temporary insulator 418 may be removed. The frontside interface 380 may be formed on upper surface of the epi-structure 320, 365. The frontside contact 310 may be formed on upper surface of the frontside interface 380.

FIGS. 4A-4D may be viewed as being portions of the frontside process. FIGS. 4E-4H may be viewed as being portions of the backside process. After the stage illustrated in FIG. 4D, remainder of the frontside processing may be completed.

Thereafter, the processing may proceed to the stage of FIG. 4E, which illustrates a stage in which a height of the temporary substrate 408 may be reduced. Lower surface of the temporary substrate 408 may still be lower than lower surface of the deep bar via 350.

FIG. 4F illustrates a stage in which the backside interface 382 may be formed on lower surface of the epi-structure 320, 365. The backside contact 312 may be formed on lower surface of the backside interface 382. This may be followed by the removal of temporary substrate 408 below the epi-structure 320, 365.

FIG. 4G illustrates a stage in which the temporary substrate 408 below the deep bar via 350 may be removed. The removed temporary substrate 408 may be replaced with the backside dielectric 362.

FIG. 4H illustrates a stage in which the backside power connect 375 may be formed on lower surface of the backside contact 312. Also, the backside power rail 370 may be formed on lower surface of the backside power connect 375.

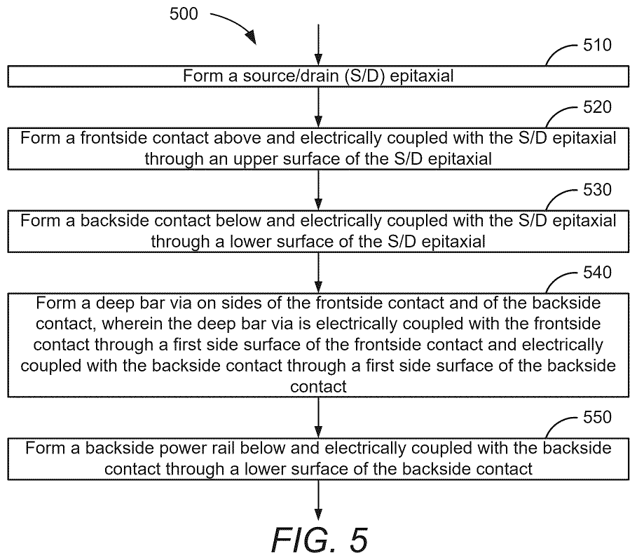

FIG. 5 illustrates a flow chart of an example method 500 of fabricating a semiconductor device, such as the semiconductor device 300, in accordance with at one or more aspects of the disclosure.

In block 510, a source/drain (S/D) epitaxial 320 may be formed.

In block 520, a frontside contact 310 may be formed above the S/D epitaxial 320. The frontside contact 310 may be electrically coupled with the S/D epitaxial 320 through an upper surface of the S/D epitaxial 320.

In block 530, a backside contact 312 may be formed below the S/D epitaxial 320. The backside contact 312 may be electrically coupled with the S/D epitaxial 320 through a lower surface of the S/D epitaxial 320.

In block 540, a deep bar via 350 may be formed on sides of the frontside contact 310 and of the backside contact 312. The deep bar via 350 may be electrically coupled with the frontside contact 310 through a first side surface of the frontside contact 310. The deep bar via 350 may also be electrically coupled with the backside contact 312 through a first side surface of the backside contact 312.

In block 550, a backside power rail 370 may be formed below the backside contact 312. The backside power rail 370 may be electrically coupled with the backside contact 312 through a lower surface of the backside contact 312.

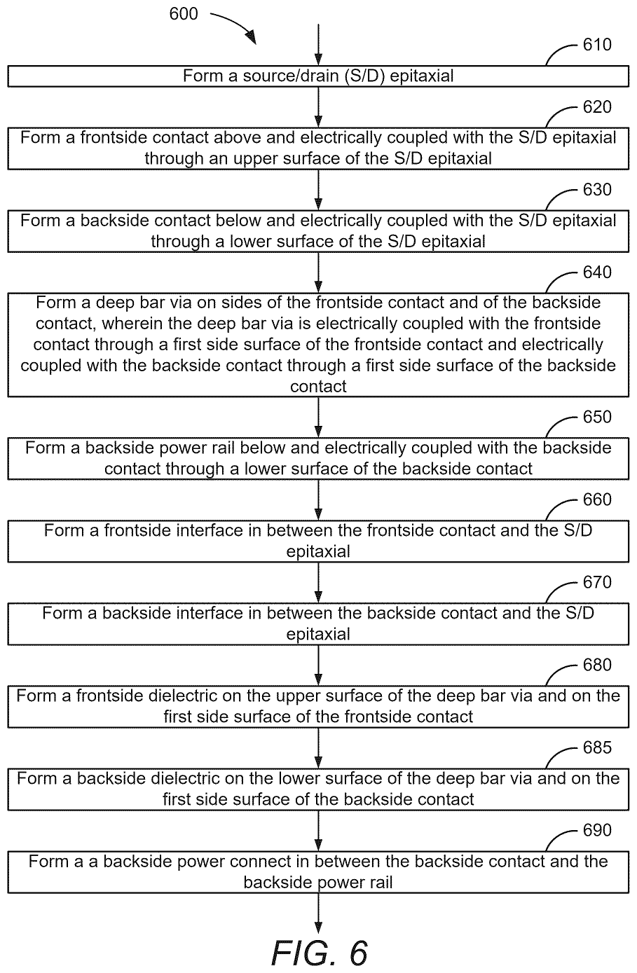

FIG. 6 illustrates a flow chart of an example method 600 of fabricating a semiconductor device, such as the semiconductor device 300 in accordance with at one or more aspects of the disclosure. FIG. 6 may be viewed as being more comprehensive than FIG. 5.

Block 610 may be similar to block 510. That is, in block 610, a source/drain (S/D) epitaxial 320 may be formed.

Block 620 may be similar to block 520. That is, in block 620, a frontside contact 310 may be formed above the S/D epitaxial 320. The frontside contact 310 may be electrically coupled with the S/D epitaxial 320 through an upper surface of the S/D epitaxial 320.

Block 630 may be similar to block 530. That is, in block 630, a backside contact 312 may be formed below the S/D epitaxial 320. The backside contact 312 may be electrically coupled with the S/D epitaxial 320 through a lower surface of the S/D epitaxial 320.

Block 640 may be similar to block 540. That is, in block 640, a deep bar via 350 may be formed on sides of the frontside contact 310 and of the backside contact 312. The deep bar via 350 may be electrically coupled with the frontside contact 310 through a first side surface of the frontside contact 310. The deep bar via 350 may also be electrically coupled with the backside contact 312 through a first side surface of the backside contact 312.

In block 650, may be similar to block 550. That is, in block 650, a backside power rail 370 may be formed below the backside contact 312. The backside power rail 370 may be electrically coupled with the backside contact 312 through a lower surface of the backside contact 312.

In block 660, a frontside interface 380 may be formed in between the frontside contact 310 and the S/D epitaxial 320. The frontside interface 380 may be electrically conductive and may be in contact with a lower surface of the frontside contact 310 and with the upper surface of the S/D epitaxial 320.

In block 670, a backside interface 382 may be formed in between the backside contact 312 and the S/D epitaxial 320. The backside interface 382 may be electrically conductive and may be in contact with an upper surface of the backside contact 312 and with the lower surface of the S/D epitaxial 320.

In block 680, a frontside dielectric 360 may be formed on the upper surface of the deep bar via 350 and on the first side surface of the frontside contact 310. An upper surface of the frontside dielectric 360 may be coplanar with the upper surface of the frontside contact 310.

In block 685, a backside dielectric 362 may be formed on the lower surface of the deep bar via 350 and on the first side surface of the backside contact 312.

In block 690, a backside power connect 375 may be formed in between the backside contact 312 and the backside power rail 370. The backside power connect 375 may be electrically conductive and may be in contact with the lower surface of the backside contact 312 and with an upper surface of the backside power rail 370.

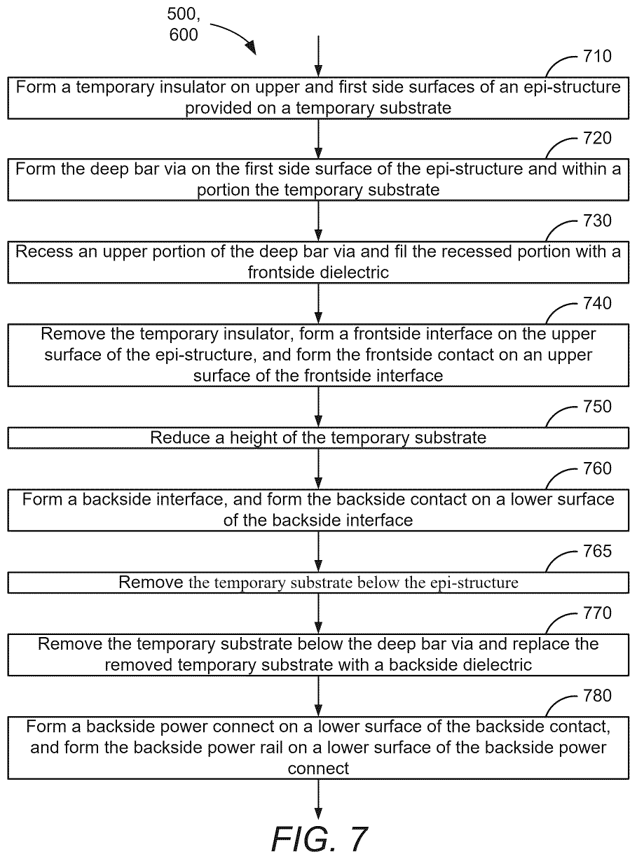

FIG. 7 illustrates a flow chart of an example process to perform the method 500, 600 of fabricating a semiconductor device in accordance with at one or more aspects of the disclosure.

In block 710, temporary insulator 418 may be formed on upper and first side surfaces of an epi-structure 320, 365. The epi-structure 320, 365 may be provided on a temporary substrate 408 prior to the temporary insulator 418 being formed. Recall that the epi-structure may comprise the S/D epitaxial 320 and epi-dielectric 365 on first and second side surfaces of the S/D epitaxial 320. Block 710 may correspond to the stage illustrated in FIG. 4A.

In block 720, deep bar via 350 may be formed on the first side surface of the epi-structure 320, 365 and within a portion the temporary substrate 408. Lower surface of the deep bar via 350 may be lower than lower surface of the epi-structure 320, 365. Block 720 may correspond to the stage illustrated in FIG. 4B.

In block 730, upper portion of the deep bar via 350 may be recessed the recessed portion may be filled with frontside dielectric 360. Block 730 may correspond to the stage illustrated in FIG. 4C.

In block 740, the temporary insulator 418 may be removed, frontside interface 380 may be formed on upper surface of the epi-structure 320, 365, and frontside contact 310 may be formed on an upper surface of the frontside interface 380. Block 740 may correspond to the stage illustrated in FIG. 4D.

While note shown, after block 740, the remainder of the frontside processing may be completed.

In block 750, a height of the temporary substrate 408 may be reduced. Lower surface of the temporary substrate 408 may be lower than the lower surface of the deep bar via 350. Block 750 may correspond to the stage illustrated in FIG. 4E.

In block 760, backside interface 382 may be formed, and backside contact 312 may be formed on a lower surface of the backside interface 382. Block 760 may correspond to the stage illustrated in FIG. 4F.

In block 765, the temporary substrate 408 below the epi-structure 320, 365 may be removed. Block 765 may also correspond to the stage illustrated in FIG. 4F.

In block 770, the temporary substrate 408 below the deep bar via 350 may be removed, and the removed temporary substrate 408 may be replaced with backside dielectric 362. Block 770 may correspond to the stage illustrated in FIG. 4G.

In block 780, backside power connect 375 may be formed on lower surface of the backside contact 312, and backside power rail 370 may be formed on lower surface of the backside power connect 375. Block 780 may correspond to the stage illustrated in FIG. 4H.

The following should be noted regarding the flow indicated in FIGS. 5-7. Unless otherwise indicated, the flow of blocks do not necessarily limit the ordering in which the blocks may be performed. In other words, the blocks may be performed in any order that is logical.

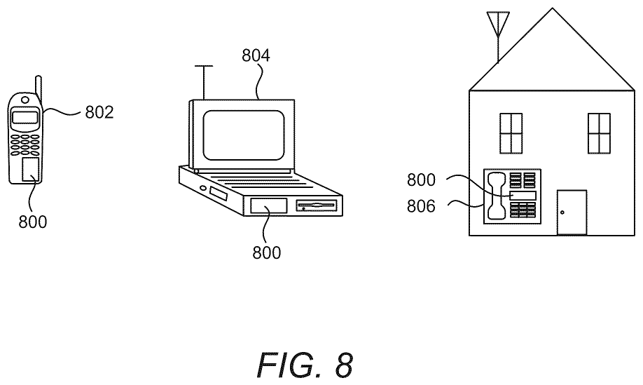

FIG. 8 illustrates various electronic devices 800 that may be integrated with any of the aforementioned semiconductor device in accordance with various aspects of the disclosure. For example, a mobile phone device 802, a laptop computer device 804, and a fixed location terminal device 806 may each be considered generally user equipment (UE) and may include one or more semiconductor devices (e.g., semiconductor device 300) as described herein. The devices 802, 804, 806 illustrated in FIG. 8 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A semiconductor device, comprising: a source/drain (S/D) epitaxial; a frontside contact above and electrically coupled with the S/D epitaxial through an upper surface of the S/D epitaxial; a backside contact below and electrically coupled with the S/D epitaxial through a lower surface of the S/D epitaxial; a deep bar via on sides of the frontside contact and of the backside contact, wherein the deep bar via is electrically coupled with the frontside contact through a first side surface of the frontside contact and electrically coupled with the backside contact through a first side surface of the backside contact; and a backside power rail below and electrically coupled with the backside contact through a lower surface of the backside contact.

Clause 2: The semiconductor device of clause 1, further comprising: a frontside interface in between the frontside contact and the S/D epitaxial, wherein the frontside interface is electrically conductive and is in contact with a lower surface of the frontside contact and with the upper surface of the S/D epitaxial; and a backside interface in between the backside contact and the S/D epitaxial, wherein the backside interface is electrically conductive and is in contact with an upper surface of the backside contact and with the lower surface of the S/D epitaxial.

Clause 3: The semiconductor device of clause 2, wherein the frontside interface is a silicide, or wherein the backside interface is a silicide, or both.

Clause 4: The semiconductor device of any of clauses 1-3, wherein an upper surface of the deep bar via is lower than an upper surface of the frontside contact, or wherein a lower surface of the deep bar via is higher than a lower surface of the backside contact, or both.

Clause 5: The semiconductor device of clause 4, further comprising: a frontside dielectric on the upper surface of the deep bar via and on the first side surface of the frontside contact; and a backside dielectric on the lower surface of the deep bar via and on the first side surface of the backside contact, wherein an upper surface of the frontside dielectric is coplanar with the upper surface of the frontside contact.

Clause 6: The semiconductor device of any of clauses 1-5, wherein the deep bar via is formed from any one or more of tungsten (W), cobalt (Co), and molybdenum (Mo).

Clause 7: The semiconductor device of any of clauses 1-6, wherein the frontside contact is formed from any one or more of tungsten (W), cobalt (Co), and molybdenum (Mo), or wherein the backside contact is formed from any one or more of tungsten (W), cobalt (Co), and molybdenum (Mo), or both.

Clause 8: The semiconductor device of any of clauses 1-7, wherein the backside power rail is formed from copper (Cu).

Clause 9: The semiconductor device of any of clauses 1-8, further comprising: a backside power connect in between the backside contact and the backside power rail, wherein the backside power connect is electrically conductive and is in contact with the lower surface of the backside contact and with an upper surface of the backside power rail.

Clause 10: The semiconductor device of clause 9, wherein the backside power connect is formed from any one or more of tungsten (W), cobalt (Co), and molybdenum (Mo).

Clause 11: The semiconductor device of any of clauses 1-10, wherein the semiconductor device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 12: A method of fabricating a semiconductor device, the method comprising: forming a source/drain (S/D) epitaxial; forming a frontside contact above and electrically coupled with the S/D epitaxial through an upper surface of the S/D epitaxial; forming a backside contact below and electrically coupled with the S/D epitaxial through a lower surface of the S/D epitaxial; forming a deep bar via on sides of the frontside contact and of the backside contact, wherein the deep bar via is electrically coupled with the frontside contact through a first side surface of the frontside contact and electrically coupled with the backside contact through a first side surface of the backside contact; and forming a backside power rail below and electrically coupled with the backside contact through a lower surface of the backside contact.

Clause 13: The method of clause 12, further comprising: forming a frontside interface in between the frontside contact and the S/D epitaxial, wherein the frontside interface is electrically conductive and is in contact with a lower surface of the frontside contact and with the upper surface of the S/D epitaxial; and forming a backside interface in between the backside contact and the S/D epitaxial, wherein the backside interface is electrically conductive and is in contact with an upper surface of the backside contact and with the lower surface of the S/D epitaxial.

Clause 14: The method of clause 13, wherein the frontside interface is a silicide, or wherein the backside interface is a silicide, or both.

Clause 15: The method of any of clauses 12-14, wherein an upper surface of the deep bar via is lower than an upper surface of the frontside contact, or wherein a lower surface of the deep bar via is higher than a lower surface of the backside contact, or both.

Clause 16: The method of any of clause 15, further comprising: forming a frontside dielectric on the upper surface of the deep bar via and on the first side surface of the frontside contact; and forming a backside dielectric on the lower surface of the deep bar via and on the first side surface of the backside contact, wherein an upper surface of the frontside dielectric is coplanar with the upper surface of the frontside contact.

Clause 17: The method of any of clauses 12-16, wherein the deep bar via is formed from any one or more of tungsten (W), cobalt (Co), and molybdenum (Mo).

Clause 18: The method of any of clauses 12-17, wherein the frontside contact is formed from any one or more of tungsten (W), cobalt (Co), and molybdenum (Mo), or wherein the backside contact is formed from any one or more of tungsten (W), cobalt (Co), and molybdenum (Mo), or both.

Clause 19: The method of any of clauses 12-18, wherein the backside power rail is formed from copper (Cu).

Clause 20: The method of any of clauses 12-19, further comprising: forming a backside power connect in between the backside contact and the backside power rail, wherein the backside power connect is electrically conductive and is in contact with the lower surface of the backside contact and with an upper surface of the backside power rail.

Clause 21: The method of any of clauses 12-20, wherein the backside power connect is formed from any one or more of tungsten (W), cobalt (Co), and molybdenum (Mo).

Clause 22: The method of any of clauses 12-21, wherein fabricating the semiconductor device comprises: forming a temporary insulator on upper and first side surfaces of an epi-structure provided on a temporary substrate, the epi-structure comprising the S/D epitaxial and an epi-dielectric on first and second side surfaces of the S/D epitaxial; forming the deep bar via on the first side surface of the epi-structure and within a portion the temporary substrate, a lower surface of the deep bar via being lower than a lower surface of the epi-structure; recessing an upper portion of the deep bar via and filling the recessed portion with a frontside dielectric; removing the temporary insulator, forming a frontside interface on the upper surface of the epi-structure, and forming the frontside contact on an upper surface of the frontside interface; reducing a height of the temporary substrate, wherein a lower surface of the temporary substrate is lower than the lower surface of the deep bar via; forming a backside interface and forming the backside contact on a lower surface of the backside interface; removing the temporary substrate below the epi-structure; removing the temporary substrate below the deep bar via and replacing the removed temporary substrate with a backside dielectric; and forming a backside power connect on a lower surface of the backside contact and forming the backside power rail on a lower surface of the backside power connect.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor device, comprising:
a source/drain (S/D) epitaxial;
a frontside contact above and electrically coupled with the S/D epitaxial through an upper surface of the S/D epitaxial;
a backside contact below and electrically coupled with the S/D epitaxial through a lower surface of the S/D epitaxial;
a deep bar via on sides of the frontside contact and of the backside contact, wherein the deep bar via is electrically coupled with the frontside contact through a first side surface of the frontside contact and electrically coupled with the backside contact through a first side surface of the backside contact; and
a backside power rail below and electrically coupled with the backside contact through a lower surface of the backside contact.

2. The semiconductor device of claim 1, further comprising:
a frontside interface in between the frontside contact and the S/D epitaxial, wherein the frontside interface is electrically conductive and is in contact with a lower surface of the frontside contact and with the upper surface of the S/D epitaxial; and
a backside interface in between the backside contact and the S/D epitaxial, wherein the backside interface is electrically conductive and is in contact with an upper surface of the backside contact and with the lower surface of the S/D epitaxial.

3. The semiconductor device of claim 2,
wherein the frontside interface is a silicide, or
wherein the backside interface is a silicide, or
both.

4. The semiconductor device of claim 1,
wherein an upper surface of the deep bar via is lower than an upper surface of the frontside contact, or
wherein a lower surface of the deep bar via is higher than a lower surface of the backside contact, or
both.

5. The semiconductor device of claim 4, further comprising:
a frontside dielectric on the upper surface of the deep bar via and on the first side surface of the frontside contact; and
a backside dielectric on the lower surface of the deep bar via and on the first side surface of the backside contact,
wherein an upper surface of the frontside dielectric is coplanar with the upper surface of the frontside contact.

6. The semiconductor device of claim 1, wherein the deep bar via is formed from any one or more of tungsten (W), cobalt (Co), and molybdenum (Mo).

7. The semiconductor device of claim 1,
wherein the frontside contact is formed from any one or more of tungsten (W), cobalt (Co), and molybdenum (Mo), or
wherein the backside contact is formed from any one or more of tungsten (W), cobalt (Co), and molybdenum (Mo), or
both.

8. The semiconductor device of claim 1, wherein the backside power rail is formed from copper (Cu).

9. The semiconductor device of claim 1, further comprising:
a backside power connect in between the backside contact and the backside power rail,
wherein the backside power connect is electrically conductive and is in contact with the lower surface of the backside contact and with an upper surface of the backside power rail.

10. The semiconductor device of claim 9, wherein the backside power connect is formed from any one or more of tungsten (W), cobalt (Co), and molybdenum (Mo).

11. The semiconductor device of claim 1, wherein the semiconductor device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

12. A method of fabricating a semiconductor device, the method comprising:
forming a source/drain (S/D) epitaxial;
forming a frontside contact above and electrically coupled with the S/D epitaxial through an upper surface of the S/D epitaxial;
forming a backside contact below and electrically coupled with the S/D epitaxial through a lower surface of the S/D epitaxial;
forming a deep bar via on sides of the frontside contact and of the backside contact, wherein the deep bar via is electrically coupled with the frontside contact through a first side surface of the frontside contact and electrically coupled with the backside contact through a first side surface of the backside contact; and
forming a backside power rail below and electrically coupled with the backside contact through a lower surface of the backside contact.

13. The method of claim 12, further comprising:
forming a frontside interface in between the frontside contact and the S/D epitaxial, wherein the frontside interface is electrically conductive and is in contact with a lower surface of the frontside contact and with the upper surface of the S/D epitaxial; and
forming a backside interface in between the backside contact and the S/D epitaxial, wherein the backside interface is electrically conductive and is in contact with an upper surface of the backside contact and with the lower surface of the S/D epitaxial.

14. The method of claim 13,
wherein the frontside interface is a silicide, or
wherein the backside interface is a silicide, or
both.

15. The method of claim 12,
wherein an upper surface of the deep bar via is lower than an upper surface of the frontside contact, or
wherein a lower surface of the deep bar via is higher than a lower surface of the backside contact, or
both.

16. The method of claim 15, further comprising:
forming a frontside dielectric on the upper surface of the deep bar via and on the first side surface of the frontside contact; and
forming a backside dielectric on the lower surface of the deep bar via and on the first side surface of the backside contact,
wherein an upper surface of the frontside dielectric is coplanar with the upper surface of the frontside contact.

17. The method of claim 12, wherein the deep bar via is formed from any one or more of tungsten (W), cobalt (Co), and molybdenum (Mo).

18. The method of claim 12,
wherein the frontside contact is formed from any one or more of tungsten (W), cobalt (Co), and molybdenum (Mo), or
wherein the backside contact is formed from any one or more of tungsten (W), cobalt (Co), and molybdenum (Mo), or
both.

19. The method of claim 12, further comprising:
forming a backside power connect in between the backside contact and the backside power rail,
wherein the backside power connect is electrically conductive and is in contact with the lower surface of the backside contact and with an upper surface of the backside power rail.

20. The method of claim 12, wherein fabricating the semiconductor device comprises:
forming a temporary insulator on upper and first side surfaces of an epi-structure provided on a temporary substrate, the epi-structure comprising the S/D epitaxial and an epi-dielectric on first and second side surfaces of the S/D epitaxial;
forming the deep bar via on the first side surface of the epi-structure and within a portion the temporary substrate, a lower surface of the deep bar via being lower than a lower surface of the epi-structure;
recessing an upper portion of the deep bar via and filling the recessed portion with a frontside dielectric;
removing the temporary insulator, forming a frontside interface on the upper surface of the epi-structure, and forming the frontside contact on an upper surface of the frontside interface;
reducing a height of the temporary substrate, wherein a lower surface of the temporary substrate is lower than the lower surface of the deep bar via;
forming a backside interface and forming the backside contact on a lower surface of the backside interface;
removing the temporary substrate below the epi-structure;
removing the temporary substrate below the deep bar via and replacing the removed temporary substrate with a backside dielectric; and
forming a backside power connect on a lower surface of the backside contact and forming the backside power rail on a lower surface of the backside power connect.
